(19) United States
(12) Patent Application Publication
(10) Pub. No.: US 2006/0192546 A1
(43) Pub. Date: Aug. 31, 2006

(54) Track-and-hold circuit

(75) Inventor: Godefridus Johannes Gertrudis Maria Geelen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 10/566,763

(22) PCT Filed: Jul. 28, 2004
(86) PCT No.: PCT/IB04/51314

§ 371 Date: Jan. 31, 2006

(30) Foreign Application Priority Data
Aug. 4, 2003 (EP) 03102417.7

(51) Int. Cl. G01R 27/22

(52) U.S. Cl. 324/94

(57) ABSTRACT

A track-and-hold circuit comprising a switch (10) and a capacitor (12). A first bootstrap switch (14a) has as its inputs a clock signal clkin and an input signal Vin. The clock signal clkboot output from the first bootstrap switch (14a) is applied to the gate of the switch (10). The first bootstrap switch (14a) is connected between the input Vin and the output Vs of the circuit via level shifting means, in the form of a current source (20), and buffer means (30). A second bootstrap switch (14b) is provided, having as its inputs the clock signal clkin and the input signal Vin. The anti-phase clock signal clknboot output from the second bootstrap switch (14b) is applied to the gates of two dummy switches (16) connected on either side of the switch (10).

This invention relates to a track-and-hold circuit and, more particularly, to a track-and-hold circuit for use in an analog-to-digital converter.

High speed analog-to-digital converts (ADC's) play a decisive role in the overall performance of many imaging, video and digital communication systems, and have been successfully developed using a number of different architectures.

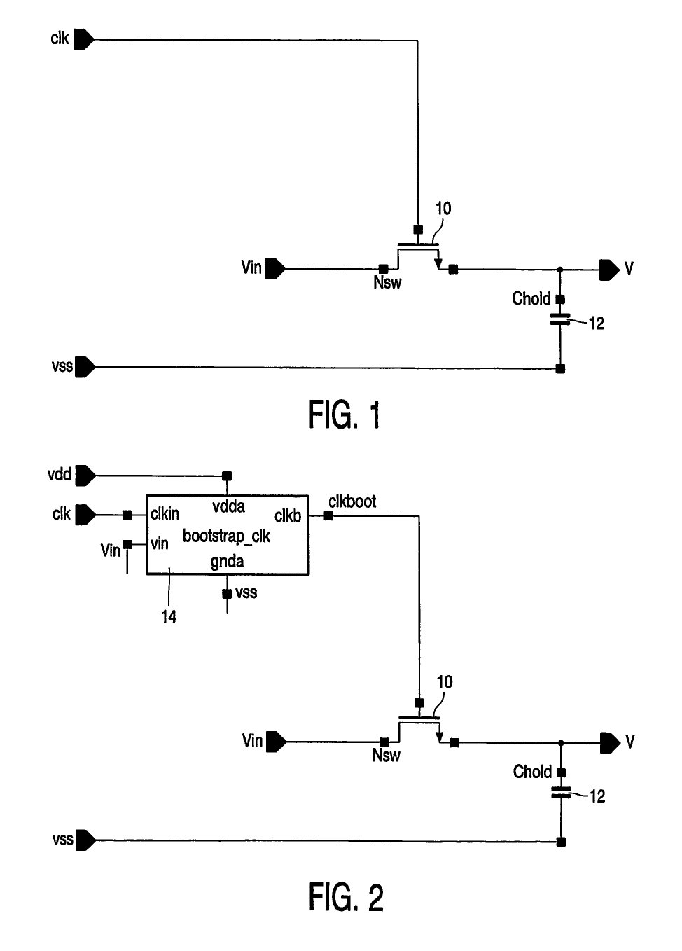

Referring to FIG. 1 of the drawings, there is illustrated a simple Track-and-Hold (T/H) circuit consisting of a switch 10 and a capacitor 12. The switch 10 can be realized using one or more MOS transistors; and is closed during a track mode of the circuit (when the capacitor charge tracks the input signal) and open during a hold mode of the circuit. There are a number of disadvantages associated with this configuration, including the fact that Ron of the switch 10 and charge injection to the capacitor 12 during switching-off is input signal dependent, and therefore introduce offset and distortion, which is clearly undesirable.

Referring to FIG. 2 of the drawings, a known solution to this problem is to provide a bootstrap circuit 14 between the clock clk and the gate of the switch 10. The bootstrap circuit 14 has an additional input terminal, and the resultant bootstrapped clock signal clkboot output from the bootstrap switch 14 is applied to the gate of the switch 10. In this way, the clock signal fed to the gate of the switch 10 follows the input signal: Vclkboot high=Vin+VDD. Now, the drive voltage Vs of the switch 10 is always equal to VDD and thus independent of Vin. As a result, distortion is suppressed, although the offset remains.

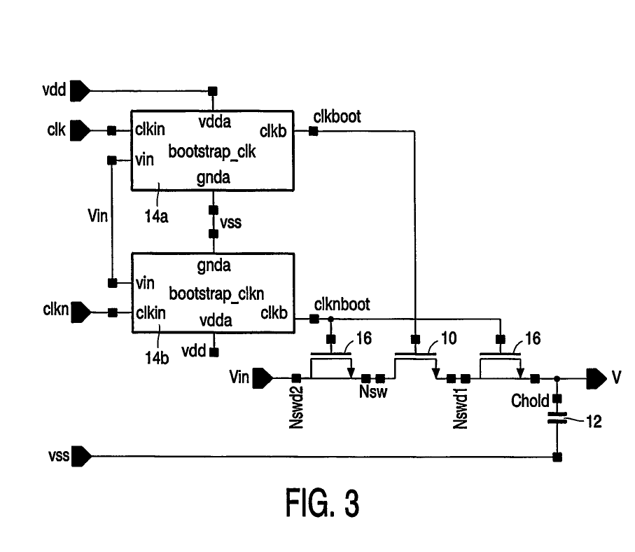

Referring to FIG. 3 of the drawings, a well known solution to this is to use dummy switches 16 which are clocked in anti-phase with the actual switch 10 and thereby compensate for the charge injection of the switch 10, so as to suppress the offset. As shown a first bootstrap switch 14a provides a bootstrapped clock signal to the gate of the switch 10, and a second bootstrap switch 14b provides a bootstrapped anti-phase clock signal to the gates of the dummy switches 16.

However, when the track-and-hold circuit is in hold mode, the clock on the dummy switches 16 is high and follows the input signal. This gives crosstalk to the sample capacitor 12 via the gate capacitance of the dummy switch 16, which again results in distortion. Furthermore, in order to achieve high bandwidth and low distortion, Vgs of the switch 10 should be maximal so as to minimize Ron of the switch 10. However, in the arrangement of FIG. 3, Vgs is only VDD−0.5V.

U.S. Pat. No. 6,525,574 B1 describes a sample and hold circuit to sample and hold an input signal, the circuit including a load capacitor to hold the signal, a switch to control the charging of the load capacitor, and a boost circuit to control the operation of the switch. The boost circuit provides an increased voltage to the gate of the switch to avoid increasing the size of the switch and effectively lowering the on resistance of the switch. It compensates for variations of the threshold voltage on the switch and the effective on resistance of the sampling switch is kept substantially constant, thereby minimizing distortion of the sample signal.

We have now devised an improved arrangement.

In accordance with the present invention, there is provided a track-and-hold circuit having an input and an output signal, a bootstrap switch having as its inputs a clock signal and an input signal, and input signal being connected to said output signal of said circuit via level shifting and buffering means; characterized in that said input signal of said bootstrap switch comprises said output signal of said circuit.

The track-and-hold circuit preferably includes two or more bootstrap switches, the input signal of each of which is connected to said output signal of said circuit via said level shifting and buffering means.

In one exemplary embodiment, the buffering means may comprise a MOS transistor, preferably a PMOS transistor.

In a preferred embodiment, the track-and-hold circuit comprises capacitor, the input signal being connected to said capacitor via a switch, said switch being closed during a track mode of said circuit and open during a hold mode of said circuit. Beneficially, one or more dummy switches may be provided, which are clocked in anti-phase to said switch connecting said input signal to said capacitor. Preferably, the input signal is connected to said dummy switches via a bootstrap switch, having as an additional input an anti-phase clock signal.

Also in accordance with the present invention, there is provided an analog-to-digital converter including a track-and-hold circuit as defined above.

These and other aspects of the invention will be apparent from and elucidated with reference to the embodiment described hereinafter.

An embodiment of the present invention will now be described by way of example only and with reference to the accompanying drawings, in which:

FIG. 1 is a schematic circuit diagram of a track-and-hold circuit according to the prior art;

FIG. 2 is a schematic circuit diagram of an improved track-and-hold circuit according to the prior art;

FIG. 3 is a schematic circuit diagram of a further improved track-and-hold circuit according to the prior art;

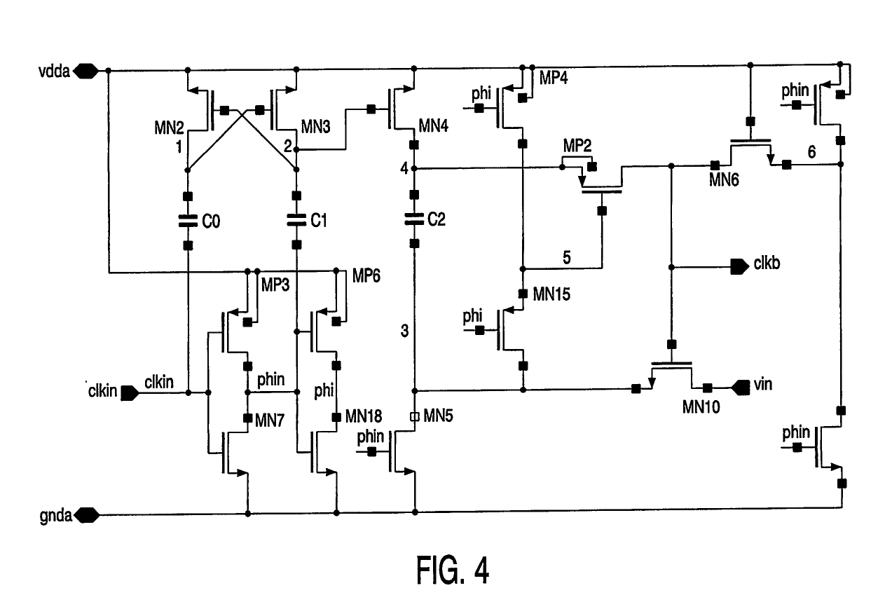

FIG. 4 is a schematic circuit diagram of a bootstrap switch for use in an exemplary embodiment of the present invention; and

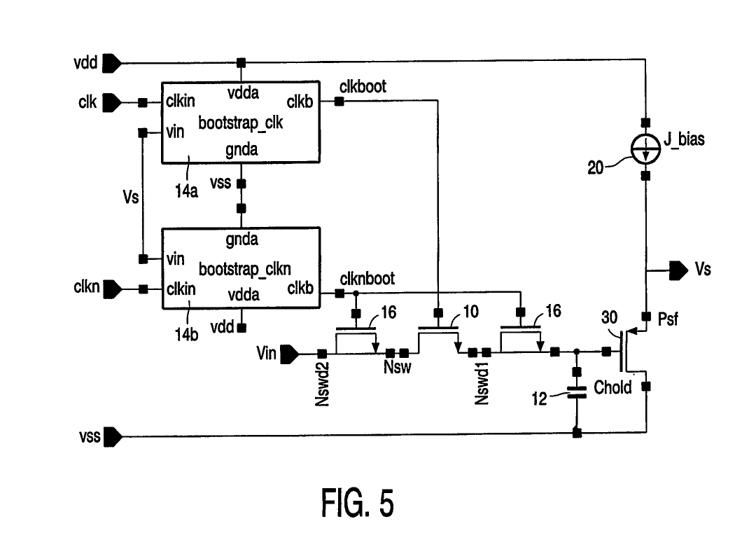

FIG. 5 is a schematic circuit diagram of a track-and-hold circuit according to an exemplary embodiment of the present invention.

Referring to FIG. 5 of the drawings, a track-and-hold circuit according to an exemplary embodiment of the present invention comprises a switch 10 and a capacitor 12, as before. A first bootstrap switch 14a has as its inputs a clock signal clk and an input signal Vs which is a level shifted version of the tracked and held input signal Vin. The clock signal clkboot output from the first bootstrap switch 14a is applied to the gate of the switch 10, and now equals Vin+Vdd and Vlevelshift Levelshifting is done in the form of a current source 20 and buffer means 30. The drive voltage Vgs of switch 10 is now Vdd+Vlevelshift=Vdd+0.5V, which is higher than in the arrangement of FIG. 3.

A second bootstrap switch 14b is provided, having as its inputs an anti-phase clock signal clk and the levelshifted input signal Vs. The anti-phase clock signal clknboot output from the second bootstrap switch 14b is applied to the gates of two dummy switches 16 connected on either side of the switch 10. Note that Vs is constant in hold mode so there is no crosstalk to the sample capacitor 12, as opposed to the case in the arrangement of FIG. 3.

There are several different configurations of a bootstrap switch, one of which is illustrated in FIG. 4. Other implementations of bootstrap techniques are well-known in the art, and the present invention is not intended to be limited in this regard.

The track-and-hold circuit illustrated in FIG. 5 may be used as the input to, for example, an 8-bit analog-to-digital converter, in which configuration it can be shown to display good performance up to 500 MHz, thereby proving the high bandwidth and low distortion of the present invention.

It should be noted that the above-mentioned embodiment illustrates rather than limits the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. The invention may be implemented by means of hardware comprising several distinct elements and by means of a suitably programmed computer. In a device claim enumerating several means, several of these mans may be embodied by one and the same item of hardware. The mere fact that certain measures are recited in mutually different dependent claims does not indicate that a combination of these measures cannot be used to advantage.

1. A track-and-hold circuit having an input (Vin) and an output signal (Vs), a bootstrap switch (14a) having as its inputs a clock signal and an input signal (Vin), said input signal (Vin) being connected to said output signal (Vs) of said circuit via level shifting (20) and buffering means (30), characterized in that said input signal of said bootstrap switch (14a) comprises said output signal (Vs) of said circuit.

2. A track-and-hold circuit according to claim 1, including two or more bootstrap switches (14a, 14b), the input signal of each of which is connected to said output signal (Vs) of said circuit via said level shifting (20) and buffering means (30).

3. A track-and-hold circuit according to claim 1, wherein said buffering means (30) comprises a MOS transistor.

4. A track-and-hold circuit according to claim 3, wherein said MOS transistor (30) is a PMOS transistor.

5. A track-and-hold circuit according to claim 1, further comprising a capacitor (12), said input signal being connected to said capacitor (12) via a switch (10), said switch (10) being closed during a track mode of said circuit and open during a hold mode of said circuit.

6. A track-and-hold circuit according to claim 5, further comprising one or more dummy switches (16) which are clocked in anti-phase to said switch (10) connecting said input signal (Vin) to said capacitor (12).

7. A track-and-hold circuit according to claim 6, wherein said input signal (Vin) is connected to said dummy switches (16) via a bootstrap switch (14b), having as an additional input an anti-phase clock signal.

8. An analog-to-digital converter including a track-and-hold circuit according to claim 1.

9. An integrated circuit including an analog-to-digital converter according to claim 8.
